(19) United States
(12) Patent Application Publication
(10) Pub. No.: US 2023/0335693 A1
(43) Pub. Date: Oct. 19, 2023

(54) MICRO-LED STRUCTURES AND PHOTOLUMINESCENT MATERIALS HAVING UV LIGHT FILTERS

(71) Applicant: Applied Materials, Inc., Santa Clara, CA (US)

(72) Inventors: Sivapackia Ganapathiappan, Los Altos, CA (US); Kulandaivelu Sivanandan, Fremont, CA (US); Lisong Xu, San Jose, CA (US); Mingwei Zhu, San Jose, CA (US); Hou T. Ng, Campbell, CA (US); Nag Patibandla, Pleasanton, CA (US)

(73) Assignee: Applied Materials, Inc., Santa Clara, CA (US)

(21) Appl. No.: 18/126,701

(22) Filed: Mar. 27, 2023

Related U.S. Application Data
(60) Provisional application No. 63/332,572, filed on Apr. 19, 2022.

(51) Int. Cl. H01L 33/58; H01L 27/15; H01L 33/50

(52) U.S. Cl. CPC H01L 33/58; H01L 27/156; H01L 33/502

(57) ABSTRACT

Exemplary device structures may include a light emitting diode structure. The light emitting diode structure may be operable to generate light. The structures may include a photoluminescent region containing a photoluminescent material. The photoluminescent region may be positioned on the light emitting diode structure. The structures may include an ultraviolet (UV) light filter positioned above the photoluminescent region. The UV light filter may be operable to absorb light generated by the light emitting diode structure characterized by an emission wavelength of less than or about 430 nm.

### CROSS-REFERENCE TO RELATED APPLICATIONS

This application claims the benefit of, and priority to U.S. Provisional Application Ser. No. 63/332,572, filed Apr. 19, 2022, which is hereby incorporated by reference in its entirety for all purposes.

### TECHNICAL FIELD

The present technology relates to micro-light-emitting diode (LED) structures and photoluminescent materials that include UV light filters. Exemplary photoluminescent materials may include quantum dots.

### BACKGROUND

High-resolution light-emitting diode (LED) displays can include millions of micron-sized pixels arranged to form a viewing screen. Conventional LED displays generate a color image by filtering down white light from an LED light source into red, green, and blue pixels that emit at varying intensities across the viewing screen. Other LED displays excite organic or inorganic compounds so they emit light of a particular color, such as red, green, or blue light, depending on the pixel. These LED displays typically require fewer filters to block the light of unwanted colors, which can improve their brightness and power efficiency. However, there can be wide variations in the emission characteristics and lifetimes of the light-emitting materials, making it difficult to display images with an accurate color gamut and stable, consistent color characteristics over a long lifetime. Furthermore, the lack of filters may allow harmful light to escape the display and reach a user.

Thus, there is a need for pixel and display designs including excitable light-emitting materials that block harmful light from reaching a user. These and other needs are addressed by the present technology.

### SUMMARY

Embodiments of the present technology include device structures that include a light emitting diode structure. The light emitting diode structure may be operable to generate light. The structures may include a photoluminescent region containing a photoluminescent material. The photoluminescent region may be positioned on the light emitting diode structure. The structures may include an ultraviolet (UV) light filter positioned above the photoluminescent region. The UV light filter may be operable to transmit light generated by the light emitting diode structure characterized by an emission wavelength of less than or about 430 nm.

In some embodiments, the photoluminescent material may include a red quantum dot material, a green quantum dot material, or a blue quantum dot material. The UV light filter may be characterized by a thickness of less than or about 200 μm. The UV light filter may be characterized by a transmittance percentage of greater than or about 80% of light having an emission wavelength of greater than or about 430 nm. The UV light filter may be characterized by a transmittance percentage of less than or about 10% of light having an emission wavelength of less than or about 430 nm. The structures may include a backplane in electronic communication with the light emitting diode structure. The backplane may be operable to activate the light emitting diode structure. The structures may include a buffer layer disposed between the photoluminescent material and the UV light filter. The buffer layer may be or include silicon nitride. The structures may include an upper layer overlying the UV light filter. The upper layer comprises silicon nitride, polymeric material, or glass.

Some embodiments of the present disclosure encompass device structures. The structures may include a backplane. The structures may include a subpixel in electronic communication with the backplane. The subpixels may include a light emitting diode structure operable to generate light. The subpixels may include a photoluminescent region containing a photoluminescent material operable to emit red, green, or blue light. The photoluminescent region may be positioned on the light emitting diode structure. The structures may include an ultraviolet (UV) light filter operable to transmit light characterized by an emission wavelength of less than or about 430 nm. The UV light filter may be positioned on the photoluminescent region.

In some embodiments, the UV light filter may be characterized by a thickness of less than or about 200 The UV light filter may be characterized by a transmittance percentage of less than or about 10% of light having an emission wavelength of less than or about 430 nm. The UV light filter may be characterized by a UV exposure stability of greater than or about 10,000 hours. The UV exposure may greater than or about 50 mJ/cm² when measuring the UV exposure stability. The UV light filter may be characterized by a temperature stability of greater than or about 1,000 hours. The temperature may be greater than or about 85° C. at about 85% relative humidity when measuring the temperature stability.

Some embodiments of the present disclosure may encompass methods of fabricating a device. The methods may include forming a light emitting diode structure on a substrate. The methods may include forming a photoluminescent region on the light emitting diode structure. The methods may include forming a photoluminescent material in the photoluminescent region. The photoluminescent material is operable to emit red, green, or blue light. The methods may include forming a UV light filter on the photoluminescent region.

In some embodiments, forming of the photoluminescent material in the photoluminescent region may include depositing the photoluminescent material in the photoluminescent region and curing the photoluminescent material. The methods may include contacting a backplane to a side of the light emitting diode structure that is opposite a side in contact with the substrate. The backplane may be operable to be in electronic communication with the light emitting diode structure. The methods may include removing the substrate from the light emitting diode structure. The removal of the substrate may expose a surface of the photoluminescent region upon which the UV light filter is formed. The UV light filter may be characterized by a thickness of less than or about 200 The UV light filter may be characterized by a transmittance percentage of greater than or about 90% of light having an emission wavelength of greater than or about 430 nm.

The present technology provides numerous benefits over conventional devices by reducing or eliminating the amount of blue or UV light that may be passed out of the device. In conventional photoluminescent devices, blue or UV light may not be fully absorbed by the photoluminescent material formed above LED structure. This blue or UV light may transmit through the photoluminescent material and propagate out of the device toward a viewer. UV light filters of the present embodiments may reduce the amount of harmful blue or UV light that is able to propagate out of the device. The UV light filters may absorb light at selected wavelengths, thereby reducing the amount of harmful light able to transmit out of the device. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a flowchart with selected operations of an exemplary method of fabricating a device according to embodiments of the present technology.

FIG. 2A shows a simplified cross-sectional view of an exemplary device structure according to embodiments of the present technology.

FIG. 2B shows a bird's-eye view of an arrangement of pixel structures according to embodiments of the present technology.

FIGS. 3A-J show the development of a portion of an exemplary device according to embodiments of the present technology.

FIG. 4A-D show the development of an exemplary device using thermal imprint lithography according to embodiments of the present technology.

FIG. 5A-C show the development of an exemplary device using photoluminescent material patterned and curing according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Technological advances in high-resolutions displays include the development of micro-light-emitting-diodes (μLEDs) from inorganic semiconductor materials and the use of photoluminescent materials like quantum dots in the displays. μLEDs are made of layers of semiconductor materials, such as indium gallium nitride (InGaN), that can be arranged to emit light of a specific peak emission wavelength when excited by an applied electric field. Semiconductor fabrication processes are used to make μLEDs having a longest dimension of less than or about 50 μm and operable to emit red, green, or blue light. Quantum dots are nanometer-sized particles of inorganic materials that can emit light of a particular color after being excited by more energetic light. The color of the emitted light may depend on one or more characteristics of the particles, including their size, shape, and composition, among other characteristics. For quantum dots made of inorganic semiconductor materials, the color of the light they emit depends on an energy gap between the conduction band and the valence band of the dots. When the quantum dots are excited, one or more electrons jump from the lower-energy valence band to the higher-energy conduction band. As the excited electrons fall back down to the valence band, they emit light having a color that depends on the size of the energy gap between the valence band and the conduction band. The narrower the energy gap, the more the emitted light is shifted to the red, while the wider the energy gap, the more the emitted light is shifted to the blue. By adjusting one or more characteristics of the quantum dots that change the energy gap between the conduction and valence bands, quantum dots can be made that emit light of practically any color in the visible spectrum.

Additional advances have combined μLEDs and quantum dots in a high-resolution display. The μLEDs are independently switched on and off by electronic circuitry in a backplane control panel to generate source light that photoexcites the quantum dots. The more energetic μLED source light, such as blue or UV light, excites the quantum dots and causes them to emit light of a specific, less-energetic, color such as blue, green, orange, or red light. The excited quantum dots can emit light with improved emissions characteristics, such as a narrower band full-width-half-maximum wavelength spectrum, than the μLEDs. The ability of the quantum dots to emit a sharper color of light reduces the number of color filters and polarizers needed in a display to block unwanted colors of light from contaminating the displayed images. In many cases, the quantum-dot-containing displays are brighter, higher-contrast, and more energy-efficient than μLED displays that lack quantum dots. The combination of the μLEDs and the quantum dots produces a more energy-efficient high-resolution display with an increased number of pixels per square inch (ppi), and a sharper, more accurate color gamut, among other enhancements.

Unfortunately, challenges remain in the development of high-resolution displays that combine μLEDs with photoluminescent materials like quantum dots. One challenge is the transmission of unabsorbed blue or UV light generated by the backplane control panel out of the quantum dots. The blue or UV light may transmit out of the display and propagate towards a viewer using the device. Unabsorbed blue or UV light may have a significant impact on a viewer's eyes. Conventional strategies may not have appreciated this transmission of blue or UV light. However, with the increased usage of combining μLEDs with photoluminescent materials like quantum dots, there is a need for materials that may prevent the transmission or leakage of harmful blue or UV light.

The present technology addresses these and other problems by forming a device structure and combining it with a UV light filter. In embodiments, the device structure includes both a LED structure, such as a μLED, and a photoluminescent region containing a photoluminescent material, such as a quantum dot. The device structure may further include a UV light filter overlying the photoluminescent region. The UV light filter may reduce the amount of blue (e.g., deep blue light having an emission wavelength between about 400 nm and about 430 nm) or UV light that is able to transmit out of the device structure and propagate toward a viewer. In these embodiments, the device structure may transmit less than or about 10% of light having emission wavelength of less than or about 430 nm, which encompasses blue and UV light.

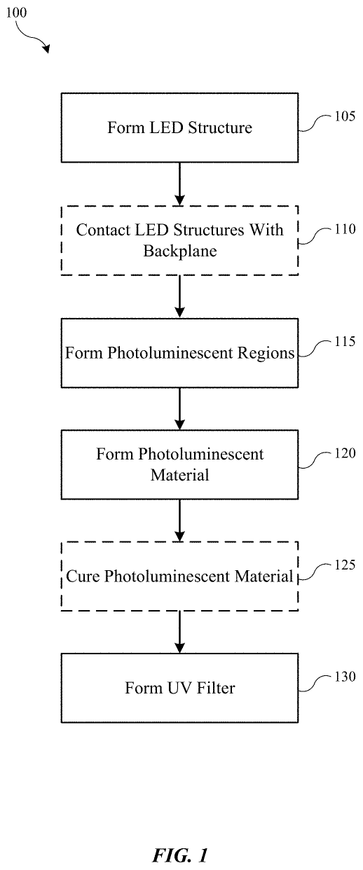

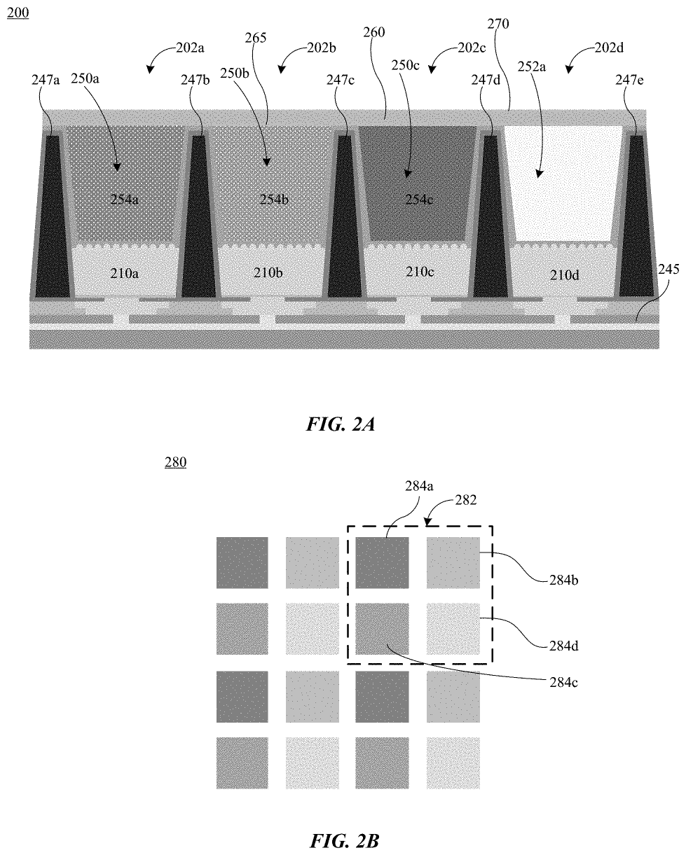

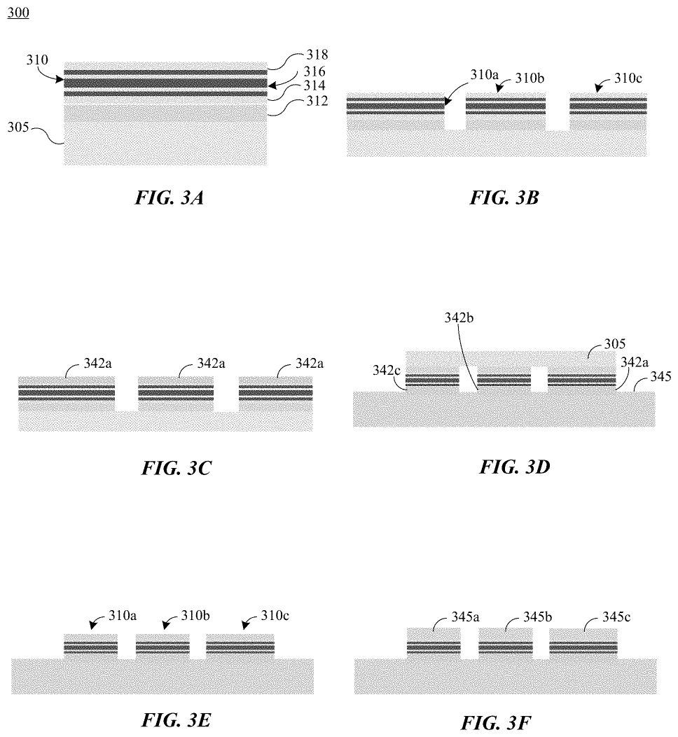

FIG. 1 shows a flowchart with selected operations in method 100 of fabricating a device according to embodiments of the present technology. Method 100 may or may not include one or more operations prior to the initiation of the method, including front-end processing, deposition, etching, polishing, cleaning, or any other operations that may be performed prior to the described operations. The method may include optional operations, which may or may not be specifically associated with some embodiments of methods according to the present technology. Method 100 describes operations to form embodiments of device structures, one of which is shown in a simplified schematic form as device structure 200 in FIG. 2A. The cross-sectional view of device structure 200 in FIG. 2A is a split-open cross-sectional view that shows the device structure, such as pixels 282 shown in FIG. 2B, that is cut between a first and second pair of subpixels and split open to reveal a cross-sectional liner arrangement of red, green, blue, and blank subpixels 202a-d. FIG. 2A illustrates only partial schematic views with limited details. In further embodiments that are not illustrated, exemplary device structures may contain additional layers, regions, and materials, having aspects as illustrated in the figures, as well as alternative structural and material aspects that may still benefit from any of the aspects of the present technology.

Method 100 includes forming a LED structure on a substrate at operation 105. In embodiments, the LED structure may be a μLED structure operable to emit blue light or UV light. In some embodiments where the substrate is removed to expose a surface upon which a photoluminescent region is formed, the LED structure may be operable to emit UV light. In additional embodiments, where the substrate forms a backplane in electronic communication with the LED structure, the LED structure may be operable to emit blue light having a peak emission wavelength in the visible blue portion of the visible spectrum. In further embodiments, the LED structure may be operable to emit light characterized by a peak emission wavelength of greater than or about 420 nm, greater than or about 430 nm, greater than or about 440 nm, greater than or about 450 nm, greater than or about 460 nm, greater than or about 470 nm, greater than or about 480 nm, greater than or about 490 nm, or more. In embodiments, the LED structure may be operable to emit light characterized by a peak emission wavelength of less than or about 430 nm, such as less than or about 420 nm, less than or about 410 nm, less than or about 400 nm, or less. While a peak emission wavelength of the LED structure may be greater than or about 430 nm, the LED structure may also emit light characterized by an emission wavelength of less than or about 430 nm, such as less than or about 420 nm, less than or about 410 nm, less than or about 400 nm, or less. For example, the LED structure may simultaneously emit light characterized by a peak emission wavelength of greater than or about 430 nm and light characterized by an emission wavelength of less than or about 430 nm (e.g., blue and/or UV light). In the embodiment of device structure 200 shown in FIG. 2A, the LED structures 210a-d formed on substrate 205 may be operable to emit blue light or UV light.

In embodiments, the LED structure may be gallium-and-nitrogen-containing LED structure. In further embodiments, the LED structure may be a gallium nitride LED structure that is epitaxially formed on a substrate or a previously formed LED structure. In additional embodiments, the substrate may be a silicon substrate or a sapphire substrate, among other kinds of substrates. In additional embodiments, the LED structure may further include an n-doped GaN layer and a p-doped GaN layer. Formed between the n-doped and p-doped GaN layers may be a multiple-quantum-well (MQW) region where the light emitted by the LED structure is generated. The LED structure may further include an electrically conductive N-pad contact that forms a pathway for electrical current to pass through the n-doped GaN layer. The LED structure may also include an electrically conductive P-pad contact that forms a pathway for electrical current to pass through the p-doped GaN layer. The N-pad and P-pad contacts may be connected to electrically conducive layers in an LED subpixel or directly connected to contacts in the control circuitry of a backplane. In embodiments, electrical signals from the control circuitry create a flow of electrical current through the LED structure that causes light emission from the MQW regions of the structures. In additional embodiments, the MQW region is formed to emit light characterized by a repeatable peak intensity wavelength and quantum efficiency for an applied electrical signal (e.g., electrical current and/or voltage). In embodiments, the peak intensity wavelength of the light emitted from the MQW region may be a blue light wavelength or a UV light wavelength.

Method 100 may further include contacting the LED structure with a backplane at optional operation 110. In embodiments, the backplane may include contacts formed in one or more semiconductor layers that independently address the LED structure. The contacts may be made of an electrically conductive material such as copper, aluminum, gold, tungsten, chromium, or nickel, among other electrically conductive materials. The LED structure may be positioned between one or more transparent electrically conductive layers that form part of the electrical conduction pathway between the LED structure and the contacts in the backplane. The transparent conductive layers may be made of indium tin oxide or indium zinc oxide, among other transparent conductive materials. A mirror layer may be positioned adjacent to the one or more transparent electrical layers to reflect light emitted by the LED structure towards the photoluminescent regions and non-photoluminescent regions. The mirror layer may be made of one or more reflective metals such as copper, aluminum, chromium, silver, platinum, or molybdenum, among other reflective metals. An electrically conductive bonding layer that bonds the LED structure to the backplane may be positioned between the mirror layer and the backplane. The electrically conductive bonding layer may be made of one or more conductive materials such as tin, gold, or indium, among other conductive materials. In the embodiment of device structure 200 shown in FIG. 2A, the backplane 245 is shown positioned below the LED structures 210a-d and is operable to emit blue and/or UV light.

Method 100 may also include forming photoluminescent regions (and non-photoluminescent regions) on the LED structures at operation 115. In embodiments, photoluminescent regions are regions that include one or more photoluminescent materials, such as quantum dots, that are operable to absorb light emitted from the LED structure and emit light with specific color characteristics. Non-photoluminescent regions may have the same structural and material characteristics as the photoluminescent regions except they are free of a photoluminescent material. The non-photoluminescent regions may include a gas or vacuum with low light absorbing characteristics at the wavelengths of light emitted by the LED structure. In the embodiment shown in FIG. 2A, device structure 200 includes photoluminescent regions 250a-c and non-photoluminescent region 252a.

In embodiments, the photoluminescent and non-photoluminescent regions may be formed in part from subpixel isolation structures. In further embodiments, the pixel isolation structures reduce the crosstalk generated by light from adjacent and nearby subpixels. The reduction in the intensity of light from adjacent and nearby pixels may be greater than or about 50%, greater than or about 60%, greater than or about 70%, greater than or about 80%, greater than or about 90%, greater than or about 95%, greater than or about 99%, or more.

In embodiments, the subpixel isolation structures may extend above and around the LED structure. The subpixel isolation structures may extend adjacent to and below the contact regions for the LED structure and may further extend down to the backplane of the device structure. The subpixel isolation structures may include a core column of pixel isolation material that is covered by one or more additional layers of material, such as a layer of reflective material such as aluminum or copper. The material in the core column may include a metal or a dielectric material, among other types of materials. The metal material may include one or more of silicon, tungsten, copper, and aluminum, among other metals. The dielectric material may include one or more of silicon oxide, silicon nitride, silicon carbide, a photoresist material, or a dielectric organic-polymer material, among other dielectric materials. The pixel isolation structures may have a height of greater than or about 2.5 μm, greater than or about 5 μm, greater than or about 7.5 μm, greater than or about 10 μm, greater than or about 12.5 μm, greater than or about 15 μm, greater than or about 17.5 μm, greater than or about 20 μm, or more. The pixel isolation structures may have a width of greater than or about 1 μm, greater than or about 2 μm, greater than or about 3 μm, greater than or about 4 μm, greater than or about 5 μm, greater than or about 6 μm, greater than or about 7 μm, greater than or about 8 μm, greater than or about 9 μm, greater than or about 10 μm, or more. The pixel isolation structures may have a height-to-width aspect ratio that is greater than or about 1.5:1, greater than or about 2:1, greater than or about 2.5:1, greater than or about 3:1, greater than or about 3.5:1, greater than or about 4:1, greater than or about 4.5:1, greater than or about 5:1, or more. In the embodiment shown in FIG. 2A, device structure 200 includes pixel isolation structures 247a-e.

Method 100 may include forming photoluminescent material in the photoluminescent regions at operation 120. Forming the photoluminescent material may include depositing photoluminescent precursors in the photoluminescent regions of the device structure. The photoluminescent precursors may be a mixture or slurry that includes a photo-curable fluid and one or more photoluminescent particles or compounds. The one or more photoluminescent compounds may include quantum dot materials that are operable to emit light with specific color characteristics when excited by a source light. These quantum-dot materials may include nanoparticles made of one or more kinds of inorganic semiconductor materials such as indium phosphide, zinc selenide, zinc sulfide, silicon, silicates, and graphene, and doped inorganic oxides, among other semiconductor materials. The photo-curable fluid may include one or more cross-linkable compounds, a photo-initiator, and a color conversion agent. The cross-linkable compounds may include monomers that form a polymer when cured. The monomers may include acrylate monomers, methacrylate monomers, acrylamide monomers, vinyl materials, epoxy monomers, and thiols. The cross-linkable compounds may include a negative photoresist material such as SU-8 photoresist. The photo-initiator may include phosphine oxide compounds and keto compounds, among other kinds of photo-initiator compounds that generate radicals that initiate the curing of unsaturated compounds when excited by UV light. Commercially available photo-initiator compounds include Irgacure 184, Irgacure 819, Darocur 1173, Darocur 4265, Darocur TPO, Omnicat 250, and Omnicat 550, among other photo-initiators.

Forming the photoluminescent material may include curing the photoluminescent precursor to form a photoluminescent material in at least one of the photoluminescent regions at optional operation 125. The curing operation may include selectively exposing the photoluminescent precursor in one of the photoluminescent regions to a curing light that coverts the photoluminescent precursor into the photoluminescent material. The curing light may be characterized by a peak emission wavelength short enough to activate one or more of the photo-curable compounds in the photo-curable fluid of the photoluminescent precursor. The curing light may be characterized by a peak emission wavelength of less than or about 405 nm, less than or about 400 nm, less than or about 395 nm, less than or about 390 nm, less than or about 385 nm, less than or about 380 nm, less than or about 375 nm, less than or about 370 nm, less than or about 365 nm, less than or about 360 nm, less than or about 355 nm, less than or about 350 nm, less than or about 340 nm, less than or about 330 nm, less than or about 320 nm, less than or about 310 nm, less than or about 300 nm, or less. The curing light may be supplied by the LED structure. Supplying the curing light from the LED structure may permit the self-alignment of the photoluminescent material in the photoluminescent region with the LED structure. The self-alignment of the photoluminescent material with the LED structure may be increasingly beneficial as the size of the subpixels decreases and the pixel density increases.

In embodiments, the formation of the photoluminescent material in the photoluminescent regions may include sequential operations to form photoluminescent material operable to emit light characterized by a specific peak intensity wavelength in one of the subpixels of the LED device structure. The sequential operations may include forming first photoluminescent material that includes red light emitting quantum dots in a first photoluminescent region of the LED device structure, forming a second photoluminescent material that includes green light emitting quantum dots in a second photoluminescent region of the LED device structure, and forming a third photoluminescent material that includes blue light emitting quantum dots in a third photoluminescent region of the LED device structure. Following the formation of the photoluminescent materials in the photoluminescent regions, each LED pixel may include red, green, and blue subpixels, as well as a redundant subpixel. In the embodiment shown in FIG. 2A, device structure 200 includes photoluminescent materials 254a-c in photoluminescent regions 250a-c.

Method 100 yet further includes forming a UV light filter on the photoluminescent regions and non-photoluminescent regions in operation 130. The UV light filter may be a layer, such as a dielectric layer, that absorbs blue (e.g., light up to about 430 nm) or UV light generated by the LED structure in the subpixel while transmitting the visible light emitted by the photoluminescent material in the photoluminescent regions. The dielectric layer may be a silicon oxide layer deposited by chemical vapor deposition or physical vapor deposition. The UV light filter may be made from organic polymers such as polyacrylates, polymethyl methacrylates, and copolymers of polyacrylates and polymethyl methacrylates. The UV light filter may be made from commercially available materials such as Tinuvin CarboProtect from BASF and the Clarex series and T-series from Astra Products. The UV light filter may be formed by providing a thin layer of material, such as a sheet, to the device structure or by dissolving the UV light filter in a solvent, with or without a polymeric material, and applying the UV light filter to the device structure. In embodiments where the UV light filter is dissolved in a solvent along with a polymeric material the solution may be applied using spray coating or any other coating method. The solvent may be or include, for example, toluene, butyl acetate, ethyl acetate, acetone, methyl ethyl ketone, methyl isopropyl ketone, methyl isobutyl ketone, tetrahydrofuran or dichloromethane. The polymeric material may be or include, for example, an acrylic and may include poly(methyl methacrylate), poly(methyl methacrylate-co-butyl acrylate), poly(butyl methacrylate), poly(butyl acrylate), poly(hexyl methacrylate), poly(benzyl acrylate), poly(benzyl methacrylate), polystyrene, poly(4-methylstyrene). After the UV light filter solution is applied, the solvent may be removed and may leave the UV light filter on the structure.

In embodiments, a transmittance percentage of light having an emission wavelength of greater than or about 430 nm through the UV light filter may be greater than or about 80%, such as greater than or about 82%, greater than or about 84%, greater than or about 86%, greater than or about 88%, greater than or about 90%, or more. Furthermore, a transmittance percentage of light having an emission wavelength of less than or about 430 nm through the UV light filter may be less than or about 10%, such as less than or about 7%, less than or about 5%, less than or about 3%, less than or about 2%, less than or about 1%, or less.

The UV light filter may be characterized by a thickness of less than or about 200 μm, such as less than or about 150 μm, less than or about 100 μm, less than or about 75 μm, less than or about 50 μm, less than or about 25 μm, less than or about 10 μm, such as less than or about 9 μm, less than or about 8 μm, less than or about 7 μm, less than or about 6 μm, less than or about 5 μm, or less. At thicknesses of greater than 200 μm, the overall device may be too thick for the device and/or the UV light filter may affect transmittance of light from the photoluminescent material. Due to the repeated exposure to blue and/or UV light, the UV light filter must be stable to both UV exposure and to increased temperatures. The UV light filter may have a UV exposure stability of greater than or about 10,000 hours when the UV exposure is greater than or about 50 mJ/cm². Furthermore, the UV light filter may have a temperature stability of greater than or about 1,000 hours at temperatures greater than or about 85° C. at about 85% relative humidity. In the embodiment shown in FIG. 2A, device structure 200 includes UV light filter 260.

In embodiments, a buffer layer may be formed prior to forming the UV light filter. That is, the buffer layer may be formed between the photoluminescent material and the UV light filter. The buffer layer may separate the photoluminescent material, such as quantum dots, from the UV light filter and prevent interaction between the photoluminescent material and the UV blocker layer. The buffer layer may be a dielectric material, such as silicon nitride. In the embodiment shown in FIG. 2A, device structure 200 includes buffer layer 265. In embodiments, an upper layer may be formed after forming the UV light filter. The upper layer may overly the UV light filter. The upper layer may be or include, for example, silicon nitride, a polymeric material, such as a single polymer or a mixture of polymers, or glass. Polymeric materials may include a soluble material for efficient coating applications or a UV-curable variety of polymeric materials, such as acrylic monomers. The upper layer may protect the UV light filter from interacting with other materials or contaminants, which may be present in the atmosphere, for example. In embodiments, the upper layer may be a final layer of the structure, such as a layer with touch response. In the embodiment shown in FIG. 2A, device structure 200 includes upper layer 270.

FIG. 2B shows birds-eye view of an arrangement of pixel structures 280 that includes a group of pixels 282 that each include four subpixels 284a-d. In the embodiment shown in FIG. 2B, the pixels 282 and the subpixels 284a-d that make up each of the pixels are square shaped. It will be appreciated that embodiments of subpixels 284a-d may have additional shapes, such as rectangular-shaped, parallelogram-shaped, trapezoidal-shaped, pentagonal-shaped, hexagonal-shaped, heptagonal-shaped, octagonal-shaped, nonagonal-shaped, circular-shaped, and elliptical-shaped, among other kinds of shapes. The pixels 282 may also be arranged in additional shapes such as rectangular-shaped, parallelogram-shaped, trapezoidal-shaped, circular-shaped, and elliptical-shaped, among other kinds of shapes. Each of the subpixels 284a-d may be characterized by a longest dimension (e.g., a diagonal length) that is less than or about 10 μm, less than or about 9 μm, less than or about 8 μm, less than or about 7 μm, less than or about 6 μm, less than or about 5 μm, or less. Each of the pixels 202 may be characterized by a longest dimension of less than or about 25 μm, less than or about 22.5 μm, less than or about 20 μm, less than or about 17.5 μm, less than or about 15 μm, less than or about 12.5 μm, less than or about μm, or less. The pixel structures 280 may be part of a larger arrangement of pixel structures that make up at least a portion of a high pixel density display. The display may be characterized by a pixel density of greater than or about 1,000 ppi, greater than or about 1,250 ppi, greater than or about 1,500 ppi, greater than or about 1,750 ppi, greater than or about 2,000 ppi, greater than or about 2,500 ppi, greater than or about 2,750 ppi, greater than or about 3,000 ppi, or more.

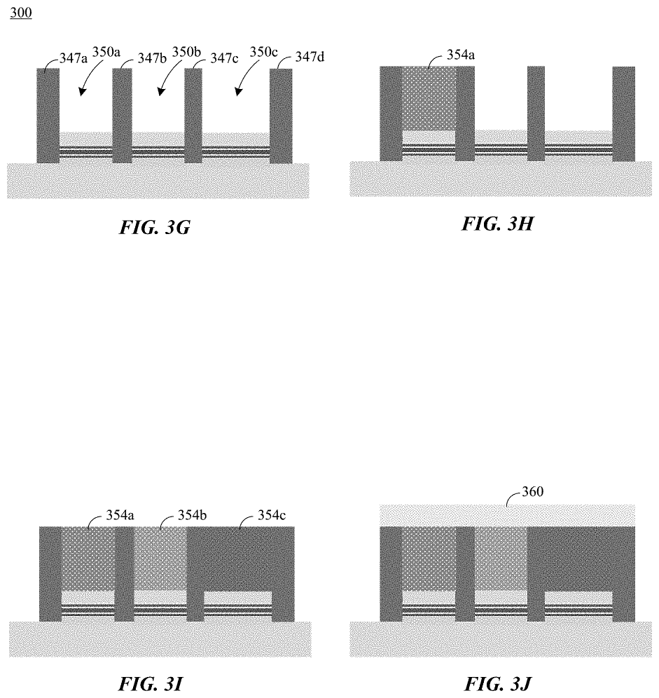

FIGS. 3A-L show the development of a device structure 300 made according an embodiment of a fabrication method that forms LED structures into subgroups of single LED structures operable to emit different wavelengths of light. FIG. 3A shows continuous layers of materials that make up LED structures 310 that is formed on a substrate 305. The substrate 305 may include silicon or sapphire, among other substrate materials. The continuous layers of materials may include the layers for the LED structures 310, which include an undoped GaN region 312, a p-doped (or n-doped) GaN region 314, a quantum well structure 316, and a n-doped (or p-doped) GaN region 318. The quantum well structure 316 may determine the color of light emitted from the LED structure 310.

FIG. 3B shows the continuous layers of materials formed into discrete LED structures on substrate 305. FIG. 3C shows contact regions 342a-c formed on LED structures 310a-c, respectively. The contact regions 342a-c may be made of one or more electrically conductive materials such as a metal, a metal alloy, or an electrically conductive metal oxide, among other electrically conductive materials. The contact regions 342a-c may be made of one or more metals such as copper, aluminum, gold, tungsten, chromium, and nickel, among other metals.

FIG. 3D shows a backplane 345 attached to the contact regions 342a-c in the device structure 300. The backplane 345 may include electronic circuitry to regulate electrical current passing through the contact regions 342a-c to LED structures 310b-c, respectively. The backplane 345 may include CMOS circuitry that includes CMOS transistors that are operable to turn on and off the flow of electrical current to the LED structures.

FIG. 3E shows the substrate 305 removed from the LED structures 310a-c in the device structure 300. The substrate 305 may be removed by one or more operations, including etching the substrate and detaching the substrate from the LED structures 310a-c. A detachment operation may include detaching the substrate 305 from a detachment layer (not shown) positioned between the substrate and the undoped GaN regions 312 of the LED structures 310a-c.

FIG. 3F shows the inclusion of optically transparent regions 345a-c on the LED structures 310a-c, respectively, in the device structure 300. The optically transparent regions 345a-c may be characterized by a high optical transmittance at the wavelengths of light emitted by the LED structures 310a-c. The optically transparent regions 345a-c may be characterized by an optical transmittance at these wavelengths of greater than or about 80%, greater than or about 85%, greater than or about 90%, greater than or about 95%, greater than or about 99%, or more. The optically transparent regions 345a-c may include an optically transparent organic polymer or an optically transparent inorganic material. The optically transparent inorganic material may include an electrically conductive optically transparent material such as indium-tin-oxide (ITO).

FIG. 3G shows the inclusion of subpixel isolation structures 347a-d between the LED structures 310a-c in the device structure 300. The subpixel isolation structures 347a-d may be made of reflective and conductive materials (e.g., a metal) and may be surrounded by electrically insulating passivation layers to prevent the subpixel isolation structures from shorting the contact regions 342a-c and the LED structures 310a-c. The subpixel isolation structures 347a-d may form sidewalls for the photoluminescent regions 350a-c.

FIG. 3H shows the inclusion of a first photoluminescent material 354a in the first photoluminescent region 350a in the device structure 300. In embodiments, the first photoluminescent material 354a may include a quantum dot material that is operable to emit red light. FIG. 3I shows the inclusion of a second photoluminescent material 354b and a third photoluminescent material 354c in the second photoluminescent region 350b and the third photoluminescent region 350c, respectively, in the device structure 300. The second photoluminescent material 354b may include a quantum dot material that is operable to emit red light. The third photoluminescent material 354c may include a quantum dot material that is operable to emit blue light.

FIG. 3J shows the inclusion of UV light filter 360 on the LED structures 310a-c in the device structure 300. The UV light filter 360, as previously described, may absorb blue and UV light generated by LED structures 310a-b while passing the visible light emitted from the photoluminescent regions 350a-c.

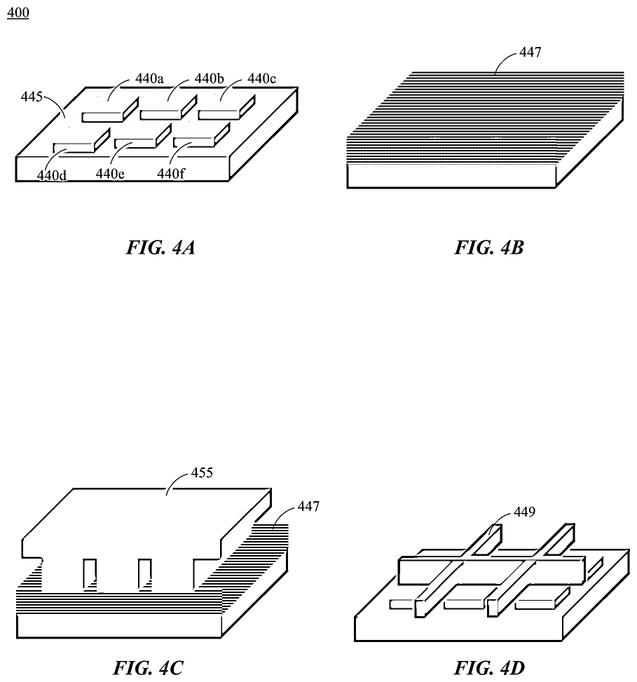

In embodiments of the present technology, photoluminescent regions may be formed on the LED structures using thermal imprinting lithography. This technique can replace a complex sequence of operations that include depositions, mask patterning, etching, and mask removal with a simplified series of operations that include the deposition of a subpixel isolation material on the LED structures and thermal imprinting of photoluminescent regions on the subpixel isolation material. FIGS. 4A-D show the development of an exemplary device structure 400 using thermal imprint lithography according to embodiments of the present technology.

FIG. 4A shows a simplified planar view of a set of LED structures 440a-f formed on a backplane 445 that includes electronic circuitry to regulate electrical signals that activate the illumination of LEDs in the LED structures 440a-f. The backplane 445 may include CMOS circuitry that includes CMOS transistors that are operable to turn on and off the flow of electrical current to the LED structures 440a-f.

FIG. 4B shows a subpixel isolation material 447 deposited on the LED structures 440a-f and the backplane 445. The subpixel isolation material 447 may include a black matrix material that can cure at elevated temperatures while pressing with an imprint stamp. The subpixel isolation material 447 may include a reflective polymer material that reflects light across the range of wavelengths emitted by the LED structures 440a-f and the photoluminescent material in the photoluminescent regions formed in part by the subpixel isolation material.

FIG. 4C shows an imprint stamp 455 in contact with the subpixel isolation material 447. The imprint stamp 455 and the substrate may be heated to an elevated temperature where the subpixel isolation material 447 will cure to form the finished isolation structure. The imprint stamp 455 may include a die having a pattern operable to form photoluminescent regions in the subpixel isolation material 447. When the imprint stamp 455 is pressed into the subpixel isolation material 447, the pattern in the die may displace or remove a portion of the subpixel isolation material to form the photoluminescent regions.

FIG. 4D shows the patterned subpixel isolation material 449 that may remain on the device structure 400 after the imprint stamp 455 is removed from contact with the device structure. In embodiments, the patterned subpixel isolation material 449 may include photoluminescent regions formed over the LED structures 440a-f that were previously filled with the subpixel isolation material 447.

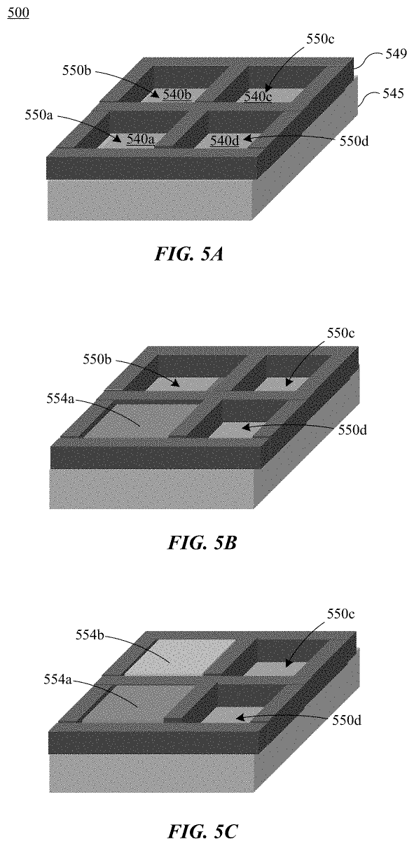

In further embodiments of the present technology, photoluminescent materials may be formed in photoluminescent regions by spin-coating and curing photoluminescent precursors on the photoluminescent regions. FIGS. 5A-C show the development of photoluminescent regions containing photoluminescent materials using spin coating and curing techniques according to embodiments of the present technology.

FIG. 5A shows a patterned device structure 500 that includes open photoluminescent regions 550a-d. The open photoluminescent regions 550a-d may be formed in part from patterned subpixel isolation material 549 formed over LED structures 540a-f and backplane 545.

FIG. 5B shows a first photoluminescent material 554a formed in photoluminescent region 550a. The first photoluminescent material 554a may be formed by applying a first photoluminescent precursor (not shown) on the empty photoluminescent regions 550a-d in the patterned device structure 500. The first photoluminescent precursor may then be selectively cured in the first photoluminescent region 550a while remaining uncured in the other photoluminescent regions 550b-d. The selective curing of the first photoluminescent precursor in the first photoluminescent region 550a may be performed by selectively irradiating the first photoluminescent region to form a photocured first photoluminescent material 554a. The uncured first photoluminescent precursor may be removed from the other photoluminescent regions 550b-d to form the patterned device structure 500 with the photoluminescent region 550a filled with photoluminescent material 554a and the other regions free of the first photoluminescent precursor. The first photoluminescent material 554a may include red quantum dots operable to emit red light when illuminated by the underlying LED structure 540a.

FIG. 5C shows the patterned device structure 500 with a second photoluminescent region 550b that includes a second photoluminescent material 554b. The second photoluminescent material 554b may be formed by applying a second photoluminescent precursor (not shown) on the empty photoluminescent regions 550b-d in the patterned device structure 500. The second photoluminescent precursor may not fill photoluminescent region 550a because the region is already filled with the first photoluminescent material 554a. The second photoluminescent precursor may then be selectively cured in the second photoluminescent region 550b while remaining uncured in the other photoluminescent regions 550c-d. The uncured second photoluminescent precursor may be removed from the other photoluminescent regions 550c-d to form the patterned device structure 500 with the photoluminescent region 550a filled with the first photoluminescent material 554a, the second photoluminescent region 550b filed with the second photoluminescent material 554b, and the other regions free of photoluminescent precursors. The second photoluminescent material 554b may include green quantum dots operable to emit green light when illuminated by the underlying LED structure 540b.

In embodiments, the third photoluminescent region 550c and/or the fourth photoluminescent region 550d may be formed by applying a second photoluminescent precursor (not shown) in the same manner as previously described with regard to the first photoluminescent region 550a and the second photoluminescent region 550b. The third photoluminescent material (not shown) may include blue quantum dots operable to emit blue light when illuminated by the underlying LED structure 540c. It is contemplated that the fourth photoluminescent region 550d may remain free of a cured photoluminescent material. The fourth photoluminescent region 550d may function as a redundant subpixel that is only filled with photoluminescent material if subpixel that includes the first, second, or third photoluminescent regions 550a-c is not functioning correctly.

Embodiments of the present technology provide displays that include combinations of LED structures and photoluminescent materials, such as quantum dots, having UV light filters overlying the photoluminescent materials. The LED structures may provide blue or UV light to activate photoluminescent materials with increased quantum efficiency. However, the light used to activate the photoluminescent materials may not be entirely absorbed by the photoluminescent materials. Instead, a portion of blue or UV light may transmit through the photoluminescent materials and propagate out of the device. If allowed to propagate out of the device, the blue or UV light may be harmful to a viewer/user. Accordingly, embodiments of the present technology may include a UV light filter overlying the photoluminescent materials, which may reduce or prevent the blue or UV light from propagating out of the device. These and other embodiments of the present technology provide high-pixel density displays with sharp, accurate color gamuts that prevent harmful light from reaching a viewer. The high-pixel density displays of the present technology may be incorporated into devices such as televisions, monitors, portable displays for phones, tablets, and laptop computers, and wearable displays for smart watches, virtual-reality headsets, and augmented-reality glasses, among other devices.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a material” includes a plurality of such materials, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A device structure comprising:
a light emitting diode structure operable to generate light;
a photoluminescent region containing a photoluminescent material, wherein the photoluminescent region is positioned on the light emitting diode structure; and
an ultraviolet (UV) light filter positioned above the photoluminescent region operable to absorb light generated by the light emitting diode structure characterized by an emission wavelength of less than or about 430 nm.

2. The device structure of claim 1, wherein the photoluminescent material comprises a red quantum dot material, a green quantum dot material, or a blue quantum dot material.

3. The device structure of claim 1, wherein the UV light filter is characterized by a thickness of less than or about 200 μm.

4. The device structure of claim 1, wherein the UV light filter is characterized by a transmittance percentage of greater than or about 80% of light having an emission wavelength of greater than or about 430 nm.

5. The device structure of claim 1, wherein the UV light filter is characterized by a transmittance percentage of less than or about 10% of light having an emission wavelength of less than or about 430 nm.

6. The device structure of claim 1, further comprising:
a backplane in electronic communication with the light emitting diode structure.

7. The device structure of claim 6, wherein the backplane is operable to activate the light emitting diode structure.

8. The device structure of claim 1, further comprising:
a buffer layer disposed between the photoluminescent material and the UV light filter.

9. The device structure of claim 8, wherein the buffer layer comprises silicon nitride.

10. The device structure of claim 1, further comprising:
an upper layer overlying the UV light filter, wherein the upper layer comprises silicon nitride, polymeric material, or glass.

11. A device structure comprising:
a backplane;
a subpixel in electronic communication with the backplane that includes:
a light emitting diode structure operable to generate light, and
a photoluminescent region containing a photoluminescent material operable to emit red, green, or blue light, wherein the photoluminescent region is positioned on the light emitting diode structure; and
an ultraviolet (UV) light filter operable to absorb light characterized by an emission wavelength of less than or about 430 nm, wherein the UV light filter is positioned on the photoluminescent region.

12. The device structure of claim 11, wherein the UV light filter is characterized by a thickness of less than or about 200 μm.

13. The device structure of claim 11, wherein the UV light filter is characterized by a transmittance percentage of less than or about 10% of light having an emission wavelength of less than or about 430 nm.

14. The device structure of claim 11, wherein the UV light filter is characterized by a UV exposure stability of greater than or about 10,000 hours, wherein the UV exposure is greater than or about 50 mJ/cm².

15. The device structure of claim 11, wherein the UV light filter is characterized by a temperature stability of greater than or about 1,000 hours, wherein a temperature is greater than or about 85° C. at about 85% relative humidity.

16. A method of fabricating a device comprising:
forming a light emitting diode structure on a substrate;
forming a photoluminescent region on the light emitting diode structure;
forming a photoluminescent material in the photoluminescent region, wherein the photoluminescent material is operable to emit red, green, or blue light; and
forming a UV light filter on the photoluminescent region.

17. The method of fabricating a device of claim 16, wherein the forming of the photoluminescent material in the photoluminescent region comprises:
depositing the photoluminescent material in the photoluminescent region; and
curing the photoluminescent material.

18. The method of fabricating a device of claim 16, wherein the method further comprises:
contacting a backplane to a side of the light emitting diode structure that is opposite a side in contact with the substrate, wherein the backplane is operable to be in electronic communication with the light emitting diode structure; and
removing the substrate from the light emitting diode structure, wherein the removal of the substrate exposes a surface of the photoluminescent region upon which the UV light filter is formed.

19. The method of fabricating a device of claim 16, wherein the UV light filter is characterized by a thickness of less than or about 200 μm.

20. The method of fabricating a device of claim 16, wherein the UV light filter is characterized by a transmittance percentage of greater than or about 90% of light having an emission wavelength of greater than or about 430 nm.
